(19) United States
(12) Patent Application Publication
(10) Pub. No.: US 2010/0060148 A1
(43) Pub. Date: Mar. 11, 2010

(54) ORGANIC LIGHT EMITTING DIODE DISPLAY

(76) Inventors: Young-In Hwang, Yongin-si (KR); Baek-Woon Lee, Yongin-si (KR); Hae-Yeon Lee, Bucheon-si (KR)

Correspondence Address: Haynes and Boone, LLP;IP Section, 2323 Victory Avenue, SUITE 700, Dallas, TX, 75219, US

(21) Appl. No.: 12/395,581

(22) Filed: Feb. 27, 2009

(30) Foreign Application Priority Data
Sep. 11, 2008 (KR) 10-2008-0089989

(51) Int. Cl. H01J 1/62; H01L 51/50

(52) U.S. Cl. 313/504; 438/29; 257/E21.532

(57) ABSTRACT

The present invention relates to an organic light emitting device. The organic light emitting device comprises a first pixel displaying a first color, a second pixel displaying a second color, a third pixel displaying a third color, and a white pixel displaying a white color according to an embodiment of the present invention, wherein each of the first, second, third, and white pixels comprises a transflective member, a pixel electrode disposed on the transflective member, an organic light emitting member disposed on the pixel electrode, and a common electrode disposed on the organic light emitting member, wherein the first pixel further comprises a first light path control member disposed under the common electrode, and a portion of the white pixel comprises a white light path control member disposed under the common electrode.

### CROSS-REFERENCE TO RELATED APPLICATION

This application claims priority to and the benefit of Korean Patent Application No. 10-2008-0089989 filed in the Korean Intellectual Property Office on Sep. 11, 2008, the entire contents of which are incorporated herein by reference.

### BACKGROUND OF THE INVENTION

(a) Field of the Invention

The present invention relates to an organic light emitting device.

(b) Description of the Related Art

An organic light emitting device is a self-emissive display device, and an additional light source is not necessary such that the organic light emitting device has lower power consumption, as well as a high response speed, wide viewing angle, and high contrast ratio.

The organic light emitting device includes a plurality of pixels such as red pixels, blue pixels, and green pixels, and images of full colors may be displayed by combining these pixels.

Each pixel of the organic light emitting device includes an organic light emitting element and a plurality of thin film transistors for driving the light emitting element.

The organic light emitting element includes an anode and a cathode, and an organic light emitting member therebetween. The organic light emitting member may emit light of one color of three primary colors of red, green and blue, or white. The materials for the organic light emitting member is varied according to the colors that the organic light emitting member emits. Generally, white light may be represented by synthesizing red, green, and blue light emitted from light emitting materials for red, green, and blue. Moreover, in a case when an organic light emitting member emits white light, color filters may be added to obtain light of a desired color.

The above information disclosed in this Background section is only for enhancement of understanding of the background of the invention and therefore it may contain information that does not form the prior art that is already known in this country to a person of ordinary skill in the art.

### SUMMARY OF THE INVENTION

An organic light emitting device is disclosed comprising a first pixel displaying a first color, a second pixel displaying a second color, a third pixel displaying a third color and a white pixel displaying a white color according to an embodiment of the present invention, wherein each of the first, second, third, and white pixels comprises a transflective member, a pixel electrode disposed on the transflective member, an organic light emitting member disposed on the pixel electrode, and a common electrode disposed on the organic light emitting member, the first pixel further comprising a first light path control member disposed under the common electrode, a portion of the white pixel further comprising a white light path control member disposed under the common electrode.

At least one of the first light path control member and the white light path control member may comprise a thin film made of a transparent material.

The first light path control member and the white light path control member may have the same thickness.

The first light path control member and the white light path control member may be formed through the same process.

At least one of the first light path control member and the white light path control member may comprise at least one of ITO, IZO, silicon oxide, and silicon nitride.

The organic light emitting device may further comprise an overcoat disposed under the transflective members of the first, second, third, and white pixels.

At least one of the first light path control member and the white light path control member may comprise protrusions and depressions formed on a surface of the overcoat.

An inclination angle of the protrusions and depressions of the first pixel may be the same as an inclination angle of the protrusions and depressions of the white pixel.

The transflective member may comprise a transflective metal member comprising silver (Ag) or aluminum (Al).

A thickness of the transflective metal member may be in a range of about 50 Å to about 200 Å.

The transflective member may further comprise an oxide conductive member disposed on or under the transflective metal member.

The oxide conductive member may comprise ITO or IZO.

The pixel electrode may comprise ITO or IZO.

The transflective member may comprise a first thin film and a second thin film.

The first thin film may comprise silicon oxide, and the second thin film may comprise silicon nitride.

The first thin film may comprise ITO or IZO, and the second thin film may comprise at least one of silicon oxide and silicon nitride.

The organic light emitting member may be a white organic light emitting member, and the first, second, and the third pixels may further comprise a first color filter, a second color filter, and a third color filter respectively disposed under the transflective member.

The organic light emitting member may comprise a first, second, a third, and a white organic light emitting member respectively disposed in the first, second, third, and white pixels.

The organic light emitting device may further comprise a second light path control member disposed under the common electrode in the second pixel.

The first, second, and white light path control members may be simultaneously formed.

The organic light emitting device may further comprise a driving transistor electrically connected to the pixel electrode, the transflective member may be made of a conductive material and may be connected to the drain electrode of the driving transistor.

The organic light emitting device may further comprise a driving transistor electrically connected to the pixel electrode, wherein the transflective member may comprise an inorganic insulating material, and the pixel electrode may be connected to the drain electrode of the driving transistor.

The organic light emitting device may further comprise a driving transistor electrically connected to the pixel electrode, wherein at least one of the first and white light path control members may comprise a thin film made of a conductive material, and the at least one of the first and white light path control members which comprises the thin film made of the conductive material is connected to a drain electrode of the driving transistor.

The first color, the second color, and the third color may be red, green, and blue, respectively.

In an organic light emitting device comprising a first pixel displaying a first color, a second pixel displaying a second color, a third pixel displaying a third color, and a white pixel displaying a white color according to another exemplary embodiment of the present invention, wherein each of the first, second, third, and white pixels comprises a reflective member, a pixel electrode disposed on the reflective member, an organic light emitting member disposed on the pixel electrode, and a transflective common electrode disposed on the organic light emitting member, the first pixel further comprising a first light path control member disposed between the common electrode ad the reflective member, a portion of the white pixel further comprising a white light path control member disposed under the common electrode.

The reflective member may comprise a reflective metal member made of at least one of aluminum, silver, Au, Pt, Ni, Cu, W, or alloys thereof.

The reflective member further may comprise an oxide conductive member disposed on or under the reflective metal member.

The oxide conductive member may comprise ITO or IZO.

A method for manufacturing an organic light emitting device comprising a first pixel displaying a first color, a second pixel displaying a second color, a third pixel displaying a third color, and a white pixel displaying a white color according to an embodiment of the present invention comprises: forming a transflective member on a substrate of each of the first, second, third, and white pixels; forming a first light path control member on the transflective member of at least one of the first, second, and the third pixels, and a white light path control member on a portion of the transflective member of the white pixel; forming a pixel electrode in each of the first, second, third, and white pixels; forming an organic light emitting member on the pixel electrode; and forming a common electrode on the organic light emitting member, wherein the first light path control member and the white light path control member are formed through a same process.

The forming of the transflective member may comprise depositing a transflective member layer comprising at least two materials having different refractive indexes; and patterning the transflective member layer by photolithography.

The forming of the transflective member may comprise sequentially depositing a lower transparent conductive layer, a metal layer, and an upper transparent conductive layer; and patterning the lower transparent conductive layer, the metal layer, and the upper transparent conductive layer by photolithography.

The lower transparent conductive layer and the upper transparent conductive layer may comprise at least one of ITO and IZO, and the metal layer comprises at least one of silver and aluminum.

At least one of the first light path control member and the white light path control member may comprise at least one of silicon nitride, silicon oxide, ITO, and IZO.

### BRIEF DESCRIPTION OF THE DRAWINGS

FIG. 1 is an equivalent circuit diagram of an organic light emitting device according to an embodiment of the present invention.

FIG. 2 is a top plan view showing an arrangement of a plurality of pixels in an organic light emitting device according to an embodiment of the present invention.

FIG. 3 is a cross-sectional view of an organic light emitting device according to an embodiment of the present invention.

FIG. 4 to FIG. 7 are cross-sectional views showing intermediate steps of a manufacturing method of the organic light emitting device shown in FIG. 3 according to an embodiment of the present invention.

FIG. 8 is a cross-sectional view of an organic light emitting device according to another embodiment of the present invention.

FIG. 9 to FIG. 11 are cross-sectional views showing intermediate steps of a manufacturing method of the organic light emitting device shown in FIG. 8 according to an embodiment of the present invention.

FIG. 12 is a cross-sectional view of an organic light emitting device according to another embodiment of the present invention.

FIG. 13 to FIG. 15 are cross-sectional views showing intermediate steps of a manufacturing method of the organic light emitting device shown in FIG. 12 according to an embodiment of the present invention.

FIG. 16 to FIG. 19 are cross-sectional views of an organic light emitting device according to another embodiment of the present invention, respectively.

### DETAILED DESCRIPTION OF THE EMBODIMENTS

The present invention will be described more fully hereinafter with reference to the accompanying drawings, in which embodiments of the invention are shown.

As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

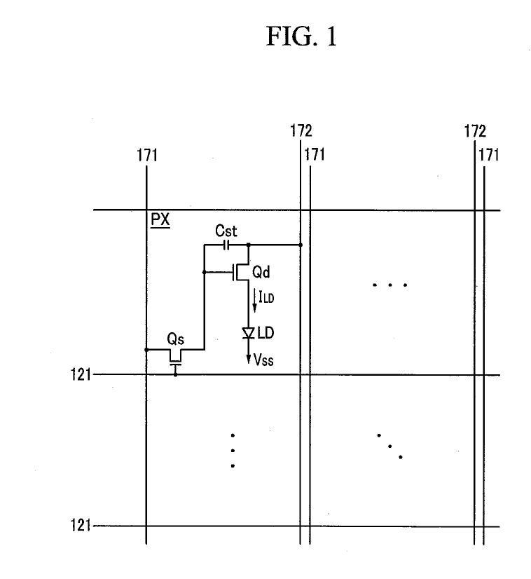

First, an organic light emitting device according to an embodiment of the present invention will be described with reference to FIG. 1.

FIG. 1 is an equivalent circuit diagram of an organic light emitting device according to an exemplary embodiment of the present invention.

Referring to FIG. 1, an organic light emitting device according to the present embodiment includes a plurality of signal lines 121, 171, and 172, and a plurality of pixels PX connected thereto and arranged substantially in a matrix.

The signal lines include a plurality of gate lines 121 for transmitting gate signals (or scanning signals), a plurality of data lines 171 for transmitting data signals, and a plurality of driving voltage lines 172 for transmitting a driving voltage. The gate lines 121 extend substantially in a row direction and substantially parallel to each other, and the data lines 171 extend substantially in a column direction and substantially parallel to each other. The driving voltage lines 172 extend substantially in a column direction. However they may extend in the row direction and the column direction forming a mesh shape.

Each pixel PX includes a switching transistor Qs, a driving transistor Qd, a capacitor Cst, and an organic light emitting element LD.

The switching transistor Qs has a control terminal connected to one of the gate lines 121, an input terminal connected to one of the data lines 171, and an output terminal connected to the driving transistor Qd. The switching transistor Qs transmits a data signal applied from the data line 171 to the driving transistor Qd in response to a gate signal applied to the gate line 121.

The driving transistor Qd has a control terminal connected to the switching transistor Qs, an input terminal connected to the driving voltage line 172, and an output terminal connected to the organic light emitting element LD. The driving transistor Qd drives an output current I_{LD} having a magnitude depending on the voltage between the control terminal and the output terminal thereof.

The capacitor Cst is connected between the control terminal and the input terminal of the driving transistor Qd. The capacitor Cst stores a data voltage applied to the control terminal of the driving transistor Qd and maintains the data voltage even after the switching transistor Qs is turned off.

The organic light emitting element LD, such as an organic light emitting diode, has an anode connected to the output terminal of the driving transistor Qd and a cathode connected to a common voltage Vss. The organic light emitting element LD emits light having an intensity depending on an output current I_{LD} of the driving transistor Qd, thereby displaying an image. The organic light emitting element LD may include an organic material uniquely emitting at least one of primary colors such as three primary colors of red, green, and blue, or white color, and the organic light emitting device displays a desired image by a spatial sum thereof.

The switching transistor Qs and the driving transistor Qd may be n-channel field effect transistors (FETs), however at least one of them may be a p-channel FET. In addition, the connection relationships among the transistors Qs and Qd, the capacitor Cst, and the organic light emitting diode LD may be modified.

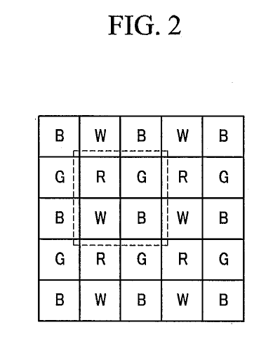

Next, a pixel arrangement of the organic light emitting device shown in FIG. 1 will be described with reference to FIG. 2.

FIG. 2 is a top plan view showing an arrangement of a plurality of pixels in an organic light emitting device according to an embodiment of the present invention.

Referring to FIG. 2, the organic light emitting device according to an embodiment of the present invention includes red pixels R for displaying a red color, green pixels G for displaying a green color, blue pixels B for displaying a blue color, and white pixels W to not display a predetermined color, which are alternately disposed. The red pixel R, the green pixel G, and the blue pixel B are elementary pixels to display full colors, and other pixels displaying different primary colors from red, green and blue may be included. The white pixels W, which are for enhancing the luminance, may be omitted.

The four pixels of a red pixel R, a green pixel G, a blue pixel B, and a white pixel W form one group and may be repeatedly arranged along the rows and/or columns. However, the arrangement of the pixels may be variously changed.

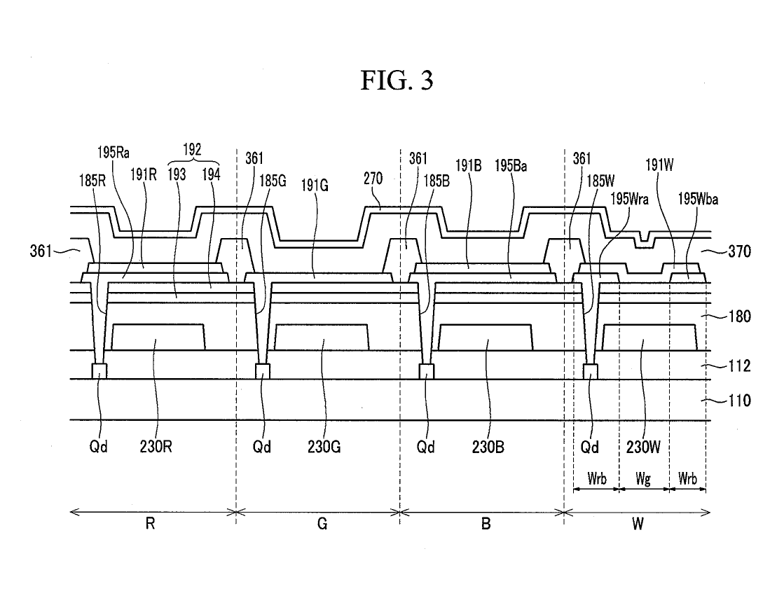

Next, a detailed structure of an organic light emitting device shown in FIG. 1 and FIG. 2 according to an embodiment of the present invention will be described with reference to FIG. 3.

FIG. 3 is a cross-sectional view of an organic light emitting device according to an embodiment of the present invention.

First, referring to FIG. 3, a thin film transistor array including a plurality of switching transistors (not shown) and a plurality of driving transistors Qd is formed on an insulation substrate 110 that may be made of transparent glass or plastic in one example. A description of the switching transistors (not shown) and the driving transistors Qd that are above-described is omitted.

An insulating layer 112 is formed on thin film transistor array.

A red color filter 230R in the red pixel R, a green color filter 230G in the green pixel G, a blue color filter 230B in the blue pixel B, and a transparent white color filter 230W in the white pixel W are formed on the insulating layer 112. The white color filter 230W of the white pixel W may be omitted.

An overcoat 180 is disposed on the color filters 230R, 230G, 230B, and 230W, and on the insulating layer 112. The overcoat 180 may be made of an organic material and have a flat surface.

The insulating layer 112 and the overcoat 180 may have a plurality of contact holes 185R, 185G, 185B, and 185W exposing a portion of the output terminals (not shown) of the driving transistors Qd.

A transflective member 192 is disposed wholly on the overcoat 180. The transflective member 192 may have a dual-layer structure including a lower layer 193 and an upper layer 194. The lower layer 193 and the upper layer 194 may be made of inorganic materials having different refractive indexes from each other in one embodiment. For example when the lower layer 193 is made of silicon nitride (SiNx), the upper layer 194 may be made of silicon oxide (SiOx). When the lower layer 193 is made of silicon oxide, the upper layer 194 may be made of silicon nitride.

In other embodiments, the transflective member 192 may comprise three or more layers that are made of materials having different refractive indexes such as silicon nitride, silicon oxide, ITO, and IZO.

In the present embodiment, incident light from above is partially reflected at the boundary between the lower layer 193 and the upper layer 194 due to the difference of the refractive indexes of the lower layer 193 and the upper layer 194 of the transflective member 192. Also, when there is a difference in the refractive indexes between the overcoat 180 and the lower layer 193, incident light from the upper direction may be partially reflected at the boundary between the overcoat 180 and the lower layer 193. Accordingly, the transflective member 192 transmits or reflects a portion of incident light.

The insulating layer 112, the overcoat 180, and the transflective member 192 may have a plurality of contact holes 185R, 185G, 185B, and 185W exposing a portion of the output terminals (not shown) of the driving transistors Qd.

Transparent members 195Ra and 195Ba are respectively disposed on the transflective members 192 of the red and blue pixels R and B, and transparent members 195Wra and 195Wba are disposed on the transflective member 192 of the white pixel W.

The transparent members 195Ra, 195Ba, and 195Wra are electrically connected to the driving transistors Qd through the contact holes 185R, 185B, and 185W, respectively. Alternatively, the transparent member 195Wba of the white pixel W may be connected to the driving transistor Qd through the contact hole 185W.

The transparent members 195Ra, 195Ba, 195Wra, and 195Wba may be made of a transparent conductive material such as indium tin oxide (ITO) or indium zinc oxide (IZO), and the thicknesses of the transparent members 195Ra, 195Ba, 195Wra, and 195Wba may be substantially equal to each other. The transparent members 195Wra and 195Wba of the white pixel W may be simultaneously formed with the transparent members 195Ra and 195Ba of the red and blue pixels R and B.

In FIG. 3, even though the transparent member 195Wra and the transparent member 195Wba are separated from each other, alternatively, they may be connected to each other.

Pixel electrodes 191R, 191G, 191B, and 191W, which are disposed on the regions corresponding to each color filter 230R, 230G, 230B, and 230W, are formed on the transparent members 195Ra, 195Ba, 195Wra, and 195Wba, and the transflective member 192. The pixel electrodes 191R, 191B, and 191W of the red, blue, and white pixels R, B, and W are electrically connected to the driving transistor Qd through the transparent members 195Ra, 195Ba, and 195Wra positioned underneath, and the pixel electrode 191G of the green pixel G is electrically connected directly to the driving transistor Qd through the contact hole 185G.

A plurality of insulating members 361 for insulation between the pixel electrodes 191R, 191B, 191G, and 191W are formed between the neighboring pixel electrodes 191R, 191G, 191B, and 191W. The insulating members 361 may be omitted.

A white organic light emitting member 370 is formed on the insulating members 361 and the pixel electrodes 191R, 191G, 191BG, and 191W, and a common electrode 270 for transmitting a common voltage Vss is formed thereon.

The white organic light emitting member 370 may have a structure in which a plurality of organic material layers emitting different colors are deposited, and the common electrode 270 may be made of a reflective metal such as calcium (Ca), barium (Ba), magnesium (Mg), aluminum (Al), and/or silver (Ag).

Alternatively, organic light emitting members (not shown) for uniquely displaying light of one color of red, green, and blue, and a white organic light emitting member, may be respectively disposed in the red, green, blue, and white pixels R, G, B, and W. In this case, the red, green, blue, or white color filters 230R, 230G, 230B, or 230W may be omitted.

In such an organic light emitting device, the pixel electrodes 191R, 191G, 191B, and 191W, the organic light emitting member 370, and the common electrode 270 form the organic light emitting element LD wherein the pixel electrodes 191R, 191G, 191B, and 191W function as an anode, and the common electrode 270 functions as a cathode.

The organic light emitting device emits light downward from the substrate 110 to display images. Light emitted toward the substrate 110 passes through the pixel electrodes 191R, 191G, 191B, and 191W and the transparent members 195Ra, 195Ba, 195Wra, and 195Wba (except for the green pixel G and a portion of the white pixel W), and arrives at the transflective member 192. The transflective member 192 reflects the incident light toward the common electrode 270, and the common electrode 270 again reflects the light toward the transflective member 192. Accordingly, the light reciprocating between the transflective member 192 and the common electrode 270 is subjected to an optical process such as interference, and passes through the transflective member 192 and the color filters 230R, 230G, 230B, and 230W to the outside.

Here, the path of light varies according to thicknesses and the refractive index of thin films between the transflective member 192 and the common electrode 270 (e.g., transparent members 195Ra, 195Ba, 195Wra, and 195Wba), such that light of wavelength corresponding to each of the primary colors may be intensified by appropriately selecting the thickness and materials of the thin films. Accordingly, light having a desired range of wavelengths and color purity for each of the primary colors may be obtained so that desired optical characteristics may be achieved. In other words, thin films such as transparent members 195Ra, 195Ba, 195Wra, and 195Wba between the transflective member and the common electrode may be utilized as light path control members.

On the other hand, in the present embodiment, transparent members 195Wra and 195Wba having the same optical conditions as the transparent members 195Ra and 195Ba of the red and blue pixels R and B are further disposed between the pixel electrode 191W and the transflective member 192 of the white pixel W. Light reciprocating between the common electrode 270 and the transflective member 192 in a first region Wrb where the transparent members 195Wra and 195Wba are existent is intensified in the wavelength range corresponding to red and blue. Light reciprocating in a second region Wg where the transparent members 195Wra and 195Wba are not presented is enhanced in the wavelength range corresponding to green. By controlling the areas of the first and second regions Wrb and Wg in the white pixel W, intensities of light having corresponding wavelengths which is enhanced by constructive interference in the respective regions Wrb and Wg may be regulated, thereby outputting white light having high luminance.

That is, the transparent members 195Wra and 195Wba having the appropriate areas may be formed in the white pixel W such that white light having enhanced luminance like the other pixels R, G, and B is emitted in the front side, thereby increasing the clarity of colors and reducing color variation and deviation of color purity according to viewing angles. Also, color variation of white light according to viewing angles may be reduced so that variation of a color coordinate may be prevented.

Also, transparent members 195Wra and 195Wba and transflective member 192, are disposed in the white pixel like the other pixels R, G, and B such that the step of the thin films between the white pixel W and the other pixels R, G, and B may be reduced and a yield of products may be increased in a manufacturing process.

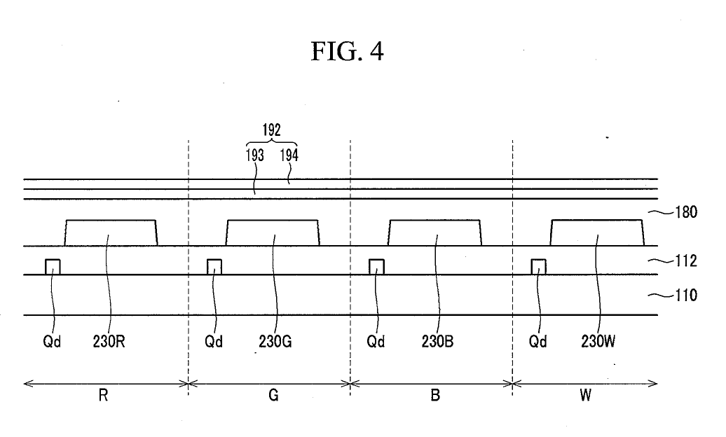

Next, a manufacturing method of the organic light emitting device shown in FIG. 3 will be described with reference to FIG. 4 to FIG. 7.

FIG. 4 to FIG. 7 are cross-sectional views showing intermediate steps of a manufacturing method of the organic light emitting device shown in FIG. 3 according to an embodiment of the present invention.

Referring to FIG. 4, a thin film transistor array including a plurality of driving transistors Qd is formed on an insulation substrate 110, an insulating layer 112, a plurality of color filters 230R, 230G, 230B, and 230W, and an overcoat 180 are sequentially formed thereon.

Next, different inorganic materials such as silicon nitride and silicon oxide are sequentially deposited on the overcoat 180 to form a transflective member 192 including a lower layer 193 and an upper layer 194. According to another embodiment, the transflective member may be made of three or more layers.

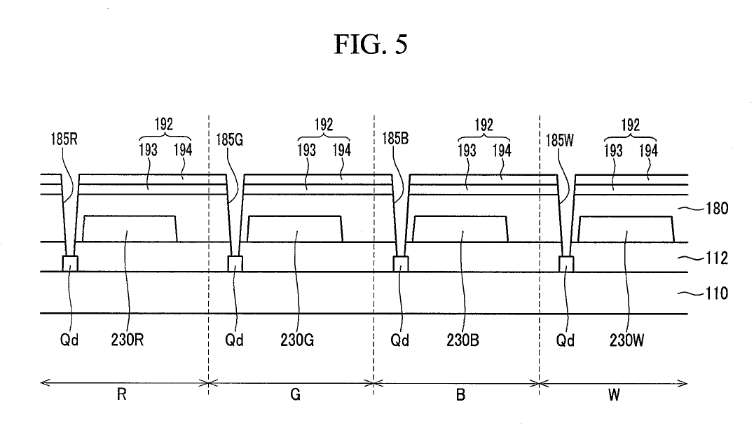

Referring to FIG. 5, the insulating layer 112, the overcoat 180 and the transflective member 192 are patterned to form a plurality of contact holes 185R, 185G, 185B, and 185W respectively on a portion of the driving transistor Qd.

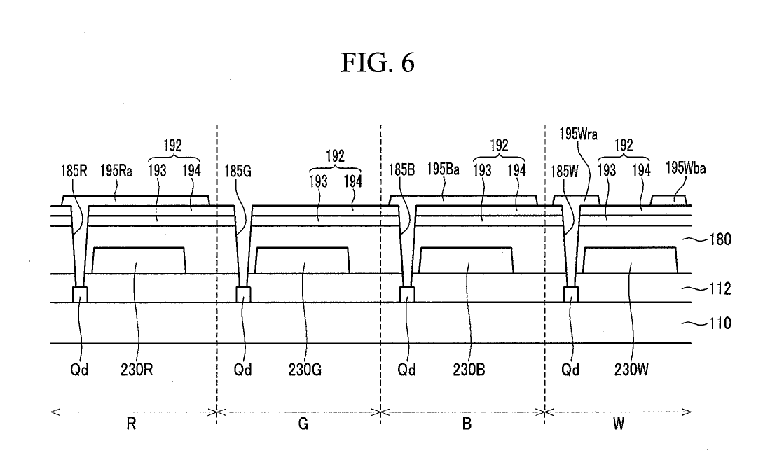

Referring to FIG. 6, a transparent conductive layer (not shown) such as ITO or IZO is deposited on the transflective member 192 by using a method such as sputtering and etched using a photosensitive film as an etch mask to form transparent members 195Ra, 195Ba, 195Wra, and 195Wba in the red, blue, and white pixels R, B, and W.

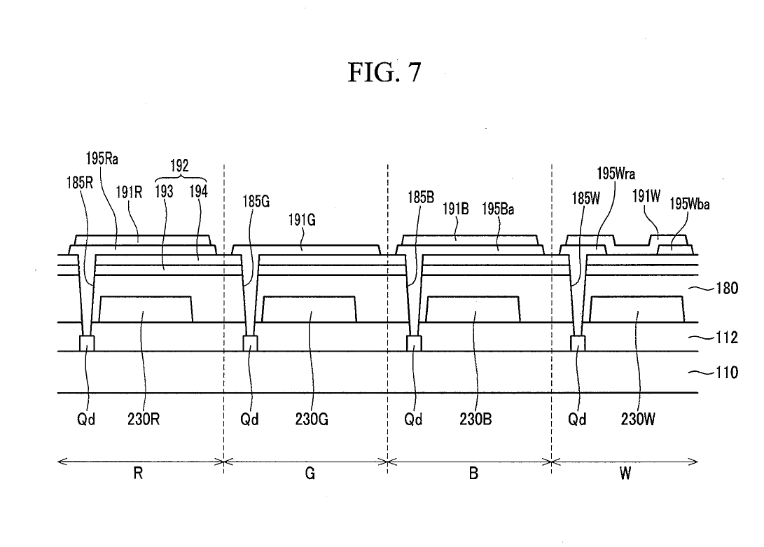

Referring to FIG. 7, a transparent conductive layer (not shown) such as ITO or IZO is deposited on the transflective member 192 or the transparent member 195Ra, 195Ba, 195Wra, and 195Wba and patterned by photolithography to form a plurality of pixel electrodes 191R, 191G, 191B, and 191W.

Finally, as shown in FIG. 3, a plurality of insulating members 361, a white organic light emitting member 370, and a common electrode 270 are sequentially formed.

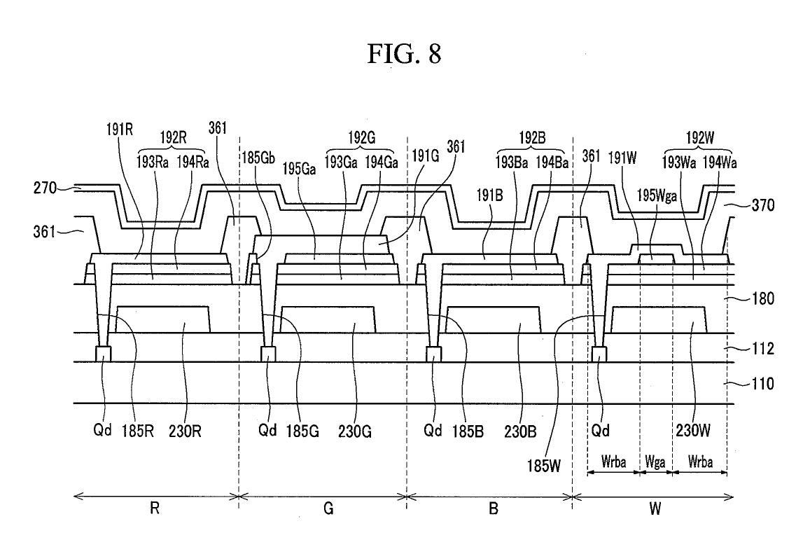

Next, an organic light emitting device according to another embodiment of the present invention will be described with reference to FIG. 8 as well as FIG. 1 and FIG. 2.

FIG. 8 is a cross-sectional view of an organic light emitting device according to another embodiment of the present invention.

In the present embodiment, descriptions of the same elements will be omitted, and the same constituent elements as in the above-described embodiment are indicated by the same reference numerals.

A thin film transistor array, an insulating layer 112, a plurality of color filters 230R, 230G, 230B, and 230W, an overcoat 180, a plurality of transflective members 192R, 192G, 192B, and 192W, a transparent member 195Ga (only corresponding to the green pixel G), pixel electrodes 191R, 191G, 191B, and 191W, insulating members 361, a white organic light emitting member 370, and a common electrode 270 are formed on an insulation substrate 110.

In the present embodiment, a plurality of transflective members 192R, 192G, 192B, and 192W are respectively disposed in the red, green, blue, and white pixels R, G, B, and W.

The transflective members 192R, 192G, 192B, and 192W have a dual-layer structure including lower layers 193Ra, 193Ga, 193Ba, and 193Wa, and upper layers 194Ra, 194Ga, 194Ba, and 194Wa. The lower layers 193Ra, 193Ga, 193Ba, and 193Wa, and the upper layers 194Ra, 194Ga, 194Ba, and 194Wa may be made of conductive materials such as ITO and IZO, or inorganic materials having different refractive indexes. For example, when the lower layers 193Ra, 193Ga, 193Ba, and 193Wa are made of silicon nitride, the upper layers 194Ra, 194Ga, 194Ba, and 194Wa may be made of silicon oxide. When the lower layers 193Ra, 193Ga, 193Ba, and 193Wa are made of silicon oxide, the upper layers 194Ra, 194Ga, 194Ba, and 194Wa may be made of silicon nitride. Also, the lower layers 193Ra, 193Ga, 193Ba, and 193Wa may be made of silicon nitride or silicon oxide, while the upper layers 194Ra, 194Ga, 194Ba, and 194Wa may be made of ITO or IZO, or vice versa. Alternatively, the transflective members 192R, 192G, 192B, and 192W may have a multilayer structure comprising at least three layers made of materials having different refractive indexes such as silicon nitride, silicon oxide, ITO, and IZO.

Also, in the present embodiment, the transparent members 195Ga and 195Wga for controlling light path lengths are disposed in the green pixel G and a portion of the white pixel W. In the present embodiment, the transparent member 195Ga may be made of an inorganic material such as silicon oxide and silicon nitride, or it may be made of a transparent conductive material such as ITO or IZO. The transparent member 195Wga of the white pixel W may be simultaneously formed with the transparent member 195Ga of the green pixel G.

The contact hole 185G exposing the driving transistor Qd in the green pixel G is formed in the insulating layer 112, the overcoat 180, the transflective member 192G, and the transparent member 195Ga. The contact holes 185R, 185B, and 185W of the remaining pixels R, B, and W are formed in the insulating layer 112, the overcoat 180, and the transflective member 192R, 192B, and 192W.

Also, in the present embodiment, differently from the previous described embodiment, the pixel electrodes 191R, 191G, 191B, and 191W of all pixels R, G, B, and W are electrically and directly connected to the driving transistor Qd through the contact holes 185R, 185G, 185B, and 185W.

Reciprocating light between the transflective members 192R, 192G, 192B, and 192W and the common electrode 270, in the red, blue, and white pixels R, B, and W and in the green pixel G is subjected to constructive interference having different light path lengths from the previous embodiment. In detail, light reciprocating in the green pixel G is subjected to constructive interference having a shorter light path length than that of the red and blue pixels R and B.

In the present embodiment, the areas of the region Wga where the transparent member 195Wga is formed in the white pixel W and the remaining region Wrba may be controlled such that light of white color having intensified luminance in the front side may also be obtained in the white pixel G and generation of color variation in the lateral side may be reduced.

Several characteristics and effects of the previous embodiment may be applied to the present embodiment.

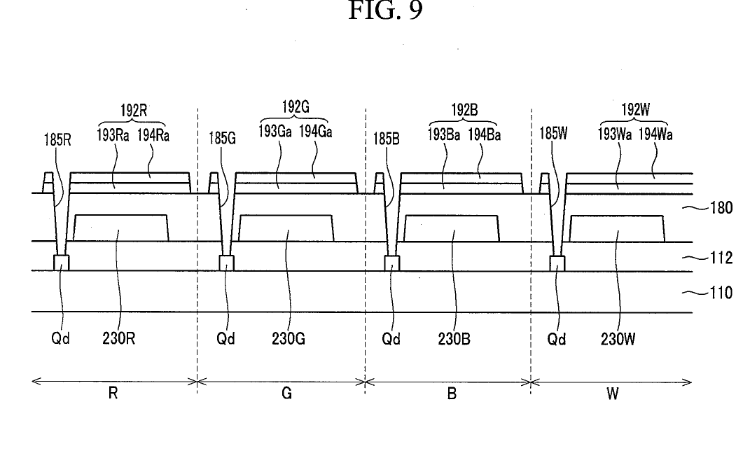

Next, a manufacturing method of the organic light emitting device shown in FIG. 8 will be described with reference to FIG. 9 to FIG. 11.

FIG. 9 to FIG. 11 are cross-sectional views showing intermediate steps of a manufacturing method of the organic light emitting device shown in FIG. 8 according to an embodiment of the present invention.

Referring to FIG. 9, like the above-described embodiment, a thin film transistor array is formed on the insulation substrate 110, and an insulating layer 112, a plurality of color filters 230R, 230G, 230B, and 230W, and an overcoat 180 are sequentially formed.

Next, materials having different refractive indexes such as silicon nitride, silicon oxide, ITO, and IZO are sequentially deposited on the overcoat 180, and then patterned to form transflective members 192R, 192G, 192B, and 192W including lower layers 193Ra, 193Ga, 193Ba, and 193Wa and upper layers 194Ra, 194Ga, 194Ba, and 194Wa. Next, the transflective members 192R, 192G, 192B, and 192W, the overcoat 180, and the insulating layer 112 are patterned by photolithography to form a plurality of contact holes 185R, 185G, 185B, and 185W.

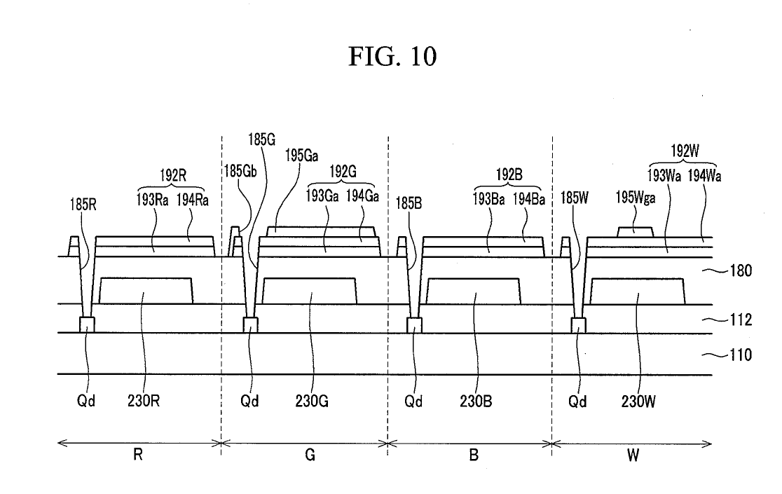

Referring to FIG. 10, a transparent material such as silicon nitride, silicon oxide, ITO, or IZO is deposited on the transflective members 192R, 192G, 192B, and 192W, and patterned by photolithography to form transparent members 195Ga and 195Wga in the green pixel G and the white pixel W. Next, the transparent members 195Ga and 195Wga of the green pixel G are patterned by photolithography to form a plurality of contact holes 185Gb disposed on the contact holes 185G. The transparent member 195Wga of the white pixel W may also include a contact hole (not shown) disposed on the contact hole 185W according to the position of the transparent member 195Wga of the white pixel W.

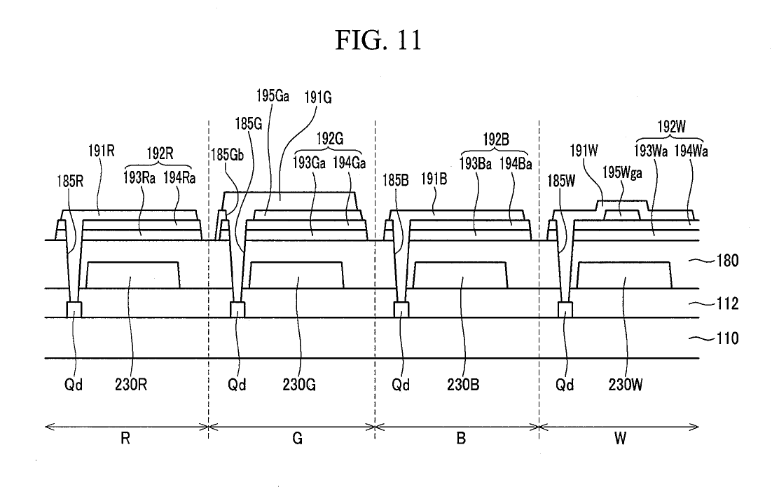

Next, referring to FIG. 11, a transparent conductive layer (not shown) such as ITO or IZO is deposited on the transflective members 192R, 192G, 192B, and 192W, or the transparent members 195Ga and 195Wga, and patterned by photolithography to form a plurality of pixel electrodes 191R, 191G, 191B, and 191W.

Finally, as shown in FIG. 8, a plurality of insulating members 361, a white organic light emitting member 370, and a common electrode 270 are sequentially formed.

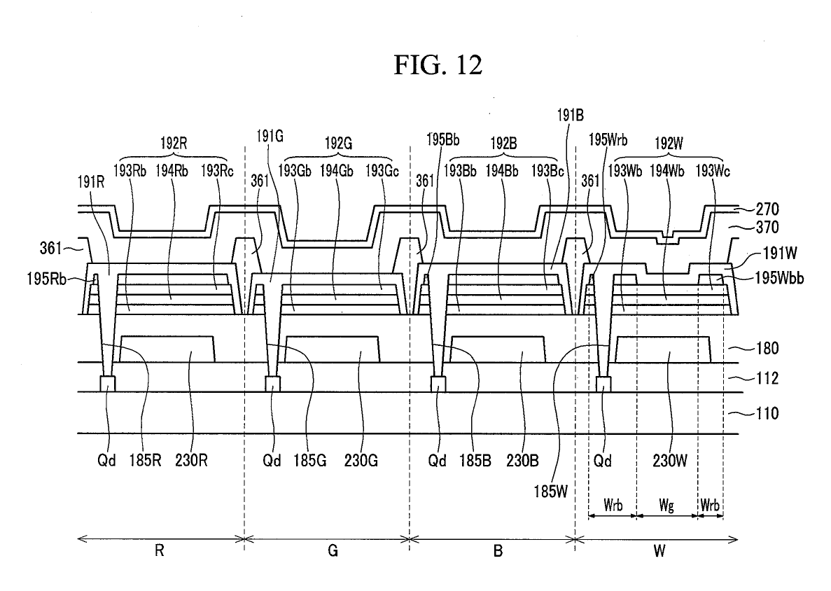

Next, an organic light emitting device according to another embodiment of the present invention will be described with reference to FIG. 12 as well as FIG. 1 and FIG. 2.

FIG. 12 is a cross-sectional view of an organic light emitting device according to another embodiment of the present invention.

In the present embodiment, descriptions of the same elements will be omitted, and the same constituent elements as in the above-described embodiment are indicated by the same reference numerals.

A thin film transistor array, an insulating layer 112, a plurality of color filters 230R, 230G, 230B, and 230W, an overcoat 180, a plurality of transflective members 192R, 192G, 192B, and 192W, transparent members 195Rb, 195Bb, 195Wrb, and 195Wbb (except for the green pixel G), pixel electrodes 191R, 191G, 191B, and 191W, an insulating member 361, a white organic light emitting member 370, and a common electrode 270 are formed on an insulation substrate 110.

In the present embodiment, a plurality of transflective members 192R, 192G, 192B, and 192W are respectively disposed in the red, green, blue, and white pixels R, G, B, and W.

The transflective members 192R, 192G, 192B, and 192W respectively include transflective metal members 194Rb, 194Gb, 194Bb, and 194Wb made of a metal, and lower and upper oxide conductive members 193Rb, 193Gb, 193Bb, 193Wb, 193Rc, 193Gc, 193Bc, and 193Wc that may be made of ITO or IZO.

The transflective metal members 194Rb, 194Gb, 194Bb, and 194Wb may be made of a metal having high reflectance such as silver (Ag) or aluminum (Al), and the thickness thereof may be in the range of about 50 Å-200 Å. Even when a metal is used, if the thickness of the metal is thin enough, the metal has transflective characteristics that incident light may be partially reflected or transmitted.

The lower oxide conductive members 193Rb, 193Gb, 193Bb, and 193Wb, and the upper oxide conductive members 193Rc, 193Gc, 193Bc, and 193Wc, are disposed on and below the transflective metal members 194Rb, 194Gb, 194Bb, and 194Wb, thereby improving cohesiveness between the transflective metal members 194Rb, 194Gb, 194Bb, and 194Wb and another layer and preventing corrosion thereof.

The transparent members 195Rb, 195Bb, 195Wrb, and 195Wbb disposed on the red and blue pixels R and B and a portion of the white pixel W may be made of silicon oxide, silicon nitride, ITO, or IZO. The transparent members 195Wrb and 195Wbb of the white pixel W are simultaneously formed with the transparent members 195Rb and 195Bb of the red and blue pixels R and B. The transparent members 195Rb, 195Bb, 195Wrb, and 195Wbb may make the light path length for reciprocating light in the red and blue pixels R and B longer than the light path length of the green pixel G. Differently from FIG. 12, the transparent members 195Wrb and 195Wbb of the white pixel W may neighbor each other and be connected to each other. Similarly, the thin films between the transflective member and the common electrode may be utilized as light path control members.

The contact holes 185R, 185G, 185B, and 185W are formed in the insulating layer 112, the overcoat 180, the transflective members 192R, 192G, 192B, and 192W and the transparent members 195Rb, 195Bb, and 195Wrb (except for the green pixel G) in respective pixels R, G, B, and W. The pixel electrodes 191R, 191G, 191B, and 191W of each of the pixels R, G, B, and W are electrically connected to the driving transistor Qd through the contact holes 185R, 185G, 185B, and 185W.

In the present embodiment, light reciprocating and being reflected between the transflective metal members 194Rb, 194Gb, 194Bb, and 194Wb and the common electrode 270 in the the red and blue pixels R and B and the region Wrb where the transparent members 195Wrb and 195Wbb are disposed is intensified in the wavelengths corresponding to red and blue. In contrast, the intensity of light corresponding to green wavelength is intensified in the green pixel G and the region Wg of the white pixel W. Accordingly, by controlling the ratio of areas of the regions Wrb and Wg, light of white color having intensified luminance in the front side may be obtained and color variation according to viewing angles may be reduced, thereby improving color reproducibility.

Many characteristics and effects of the previous embodiment may be applied to the present embodiment.

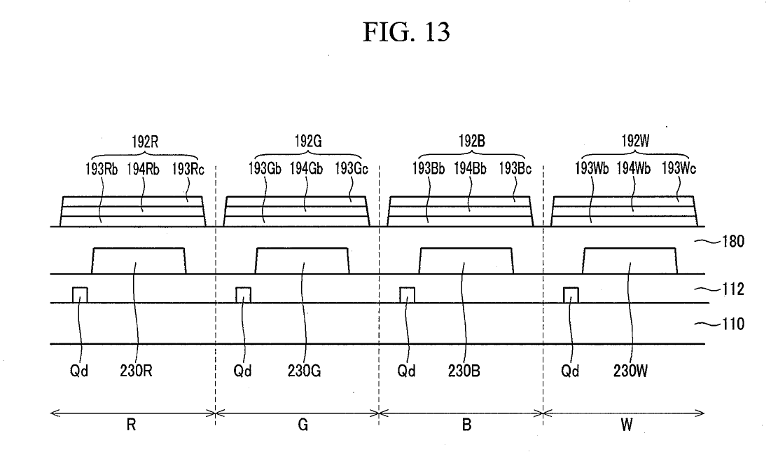

Next, a manufacturing method of the organic light emitting device shown in FIG. 12 will be described with reference to FIG. 13 to FIG. 15.

FIG. 13 to FIG. 15 are cross-sectional views showing intermediate steps of a manufacturing method of the organic light emitting device shown in FIG. 12 according to an embodiment of the present invention.

Referring to FIG. 13, a thin film transistor array including a plurality of driving transistors Qd is formed on the insulation substrate 110, and an insulating layer 112, a plurality of color filters 230R, 230G, 230B, and 230W, and an overcoat 180 are sequentially formed.

Next, a lower transparent conductive layer (not shown) such as ITO or IZO, a metal layer (not shown) such as silver or aluminum, and an upper transparent conductive layer (not shown) such as ITO or IZO are sequentially deposited on the overcoat 180 and patterned by photolithography to form transflective members 192R, 192G, 192B, and 192W including transflective metal members 194Rb, 194Gb, 194Bb, and 194Wb, and lower and upper oxide conductive members 193Rb, 193Gb, 193Bb, 193Wb, 193Rc, 193Gc, 193Bc, and 193Wc.

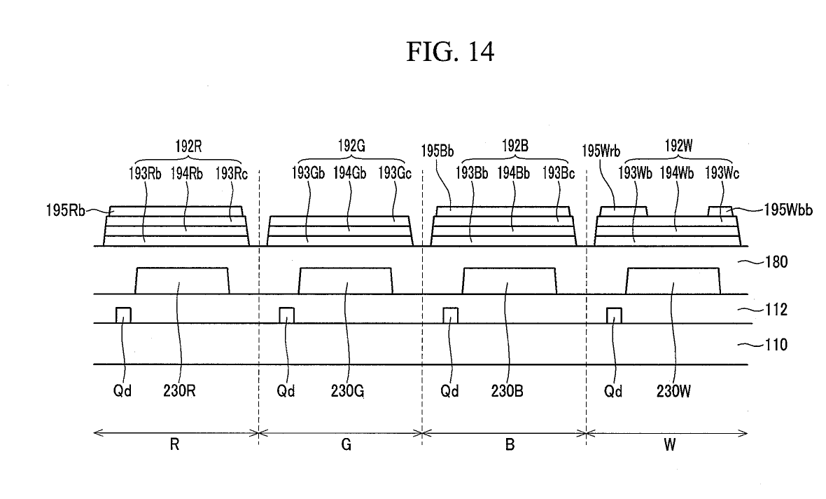

Next, referring to FIG. 14, a transparent member layer (not shown) such as silicon oxide, silicon nitride, ITO or IZO is deposited on the transflective members 192R, 192G, 192B and 192W, and patterned by photolithography to form transparent members 195Rb, 195Bb, 195Wrb and 195Wbb.

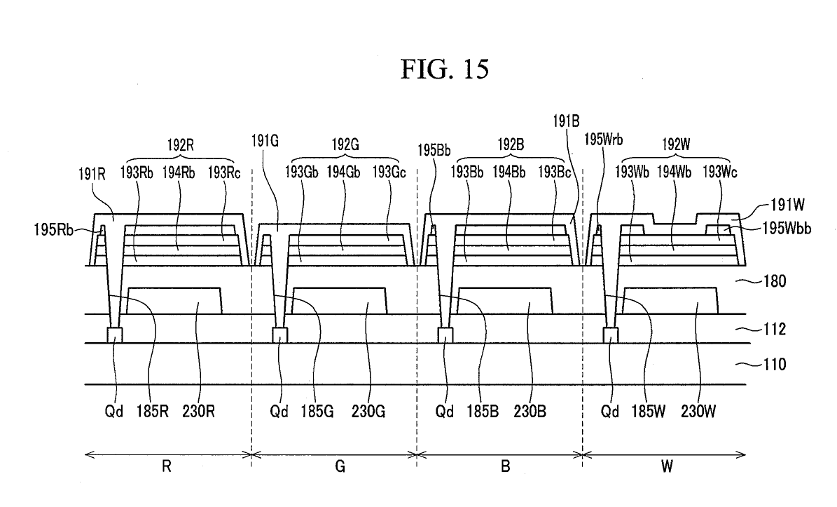

Next, referring to FIG. 15, the insulating layer 112, the overcoat 180, the transflective members 192R, 192G, 192B, and 192W and the transparent members 195Rb, 195Bb, and 195Wrb are patterned to form a plurality of contact holes 185R, 185G, 185B, and 185W, and ITO or IZO is then deposited and patterned by photolithography to form a plurality of pixel electrodes 191R, 191G, 191B, and 191W.

Finally, as shown in FIG. 12, a plurality of insulating members 361, a white organic light emitting member 370, and a common electrode 270 are sequentially formed.

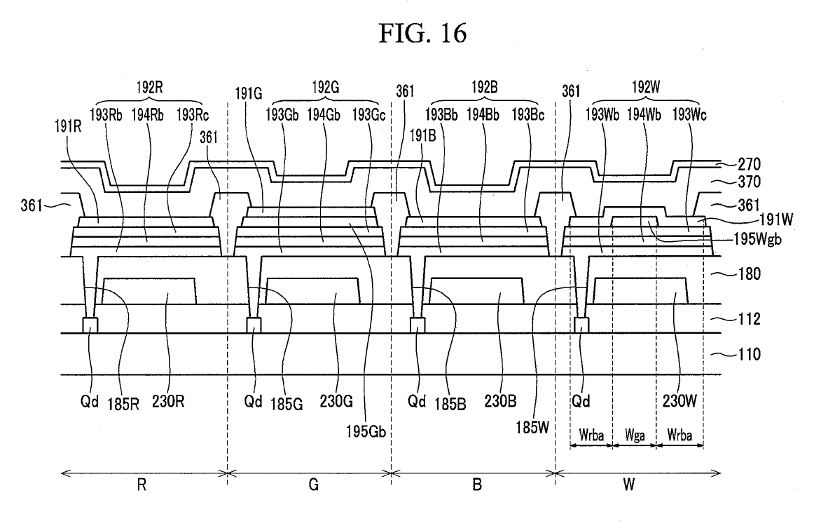

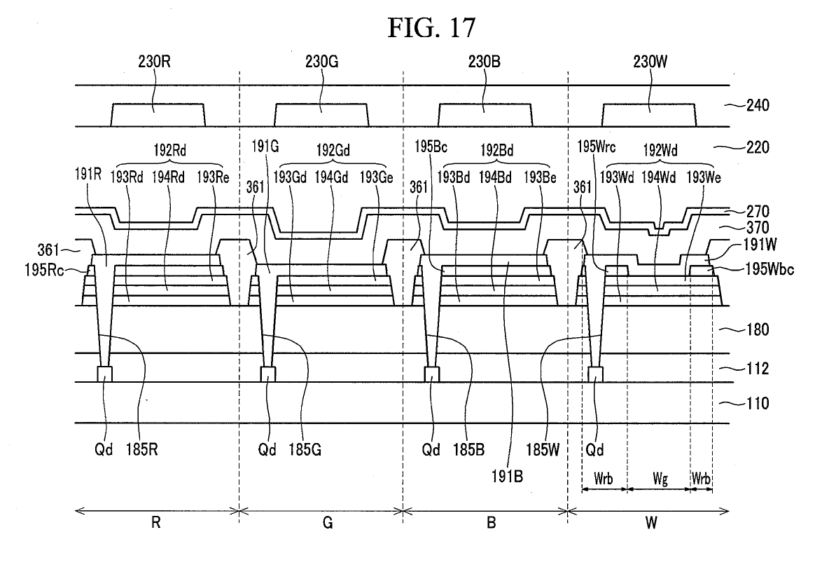

Next, an organic light emitting device according to another embodiment of the present invention will be described with reference to FIG. 16 and FIG. 17.

FIG. 16 and FIG. 17 are cross-sectional views of an organic light emitting device according to another embodiment of the present invention, respectively.

The embodiment of FIG. 16 has almost the same cross-sectional structure as the organic light emitting device of FIG. 12 such that the same description as of the embodiment of FIG. 12 is omitted, and the same constituent elements are indicated by the same reference numerals.

A thin film transistor array, an insulating layer 112, a plurality of color filters 230R, 230G, 230B, and 230W, an overcoat 180, a plurality of transflective members 192R, 192G, 192B, and 192W, a transparent members 195Gb and 195Wgb (including the portion of the green pixel G and the white pixel W), pixel electrodes 191R, 191G, 191B, and 191W, an insulating member 361, a white organic light emitting member 370 and a common electrode 270 are formed on an insulation substrate 110.

Compared with the embodiment of FIG. 12, the present embodiment includes a different structure for the contact holes 185R, 185G, 185B, and 185W, the transflective members 192R, 192G, 192B, and 192W, and the transparent members 195Gb and 195Wgb.

The contact holes 185R, 185G, 185B, and 185W are only formed in the insulating layer 112 and the overcoat 180, and the lower oxide conductive members 193Rb, 193Gb, 193Bb, and 193Wb of the transflective members 192R, 192G, 192B, and 192W are electrically and directly connected to the driving transistors Qd through the contact holes 185R, 185G, 185B, and 185W.

Also, the transparent members 195Gb and 195Wgb of the green and white pixels G and W are made of a transparent conductive material such as ITO or IZO.

The pixel electrodes 191R, 191G, 191B, and 191W are respectively applied with data signals from the driving transistors Qd through the transflective members 192R, 192G, 192B, and 192W or the transparent members 195Gb and 195Wgb.

Next, an organic light emitting device according to another embodiment of the present invention will be described with reference to FIG. 17.

A thin film transistor array, an insulating layer 112, an overcoat 180, a plurality of reflective members 192Rd, 192Gd, 192Bd, and 192Wd, transparent members 195Rc, 195Bc, 195Wrc, and 195Wbc (except for a green pixel G), pixel electrodes 191R, 191G, 191B, and 191W, an insulating member 361, a white organic light emitting member 370, a common electrode 270, a lower overcoat 220, a plurality of color filters 230R, 230G, 230B, and 230W, and an upper overcoat 240 are sequentially formed on an insulation substrate 110.

The present embodiment has almost the same sectional structure as the organic light emitting device of FIG. 12.

However, the present embodiment includes reflective members 192Rd, 192Gd, 192Bd, and 192Wd disposed on the overcoat 180.

The reflective members 192Rd, 192Gd, 192Bd, and 192Wd include lower and upper oxide conductive members 193Rd, 193Gd, 193Bd, 193Wd, 193Re, 193Ge, 193Be, and 193We that may be made of ITO or IZO and reflective metal members 194Rd, 194Gd, 194Bd, and 194Wd therebetween. The reflective metal members 194Rd, 194Gd, 194Bd, and 194Wd may be made of an opaque conductive material such as aluminum or an aluminum alloy, silver or a silver alloy, and Au, Pt, Ni, Cu, W, or alloys thereof having a high work function.

The common electrode 270 may be made of a metal including calcium (Ca), barium (Ba), magnesium (Mg), aluminum, or silver.

The color filters 230R, 230G, 230B, and 230W are disposed on the common electrode 270, and the lower and upper overcoats 220 and 240 protect the color filters 230R, 230G, 230B, and 230W and may be made of an (organic) insulating material. However, the color filter 230W may be omitted.

The organic light emitting device emits light upward from the substrate 110 to display an image. Light emitted from the organic light emitting member 370 toward the substrate 110 reciprocates between the reflective metal member 194Rd, 194Gd, 194Bd, and 194Wd and the common electrode 270, is subjected to an optical process such as interference, and passes through the color filters 230R, 230G, 230B, and 230W to go outside when appropriate conditions are satisfied.

The various characteristics and effects generated by disposing the transparent members 195Wrc and 195Wbc in the white pixel W are the same as in the previous embodiment.

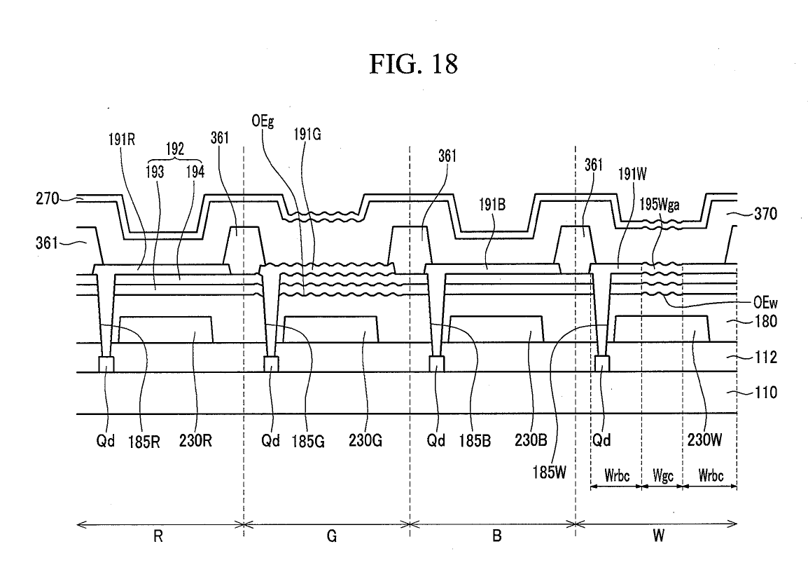

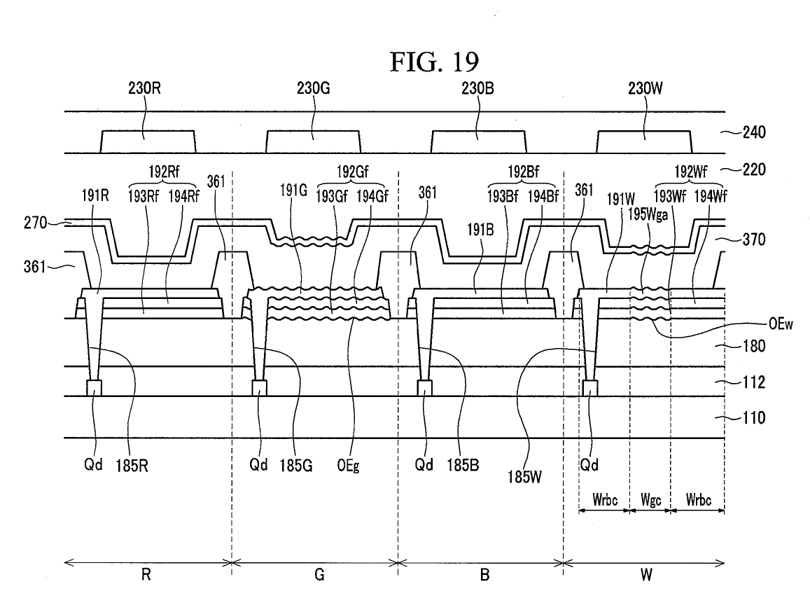

Next, an organic light emitting device according to another embodiment of the present invention will be described with reference to FIG. 18 and FIG. 19.

FIG. 18 and FIG. 19 are cross-sectional views of an organic light emitting device according to another embodiment of the present invention, respectively.

The embodiment of FIG. 18 has almost the same cross-sectional structure as the organic light emitting device of FIG. 3. The same description as of the embodiment of FIG. 3 is omitted, and the same constituent elements are indicated by the same reference numerals.

A thin film transistor array, an insulating layer 112, a plurality of color filters 230R, 230G, 230B, and 230W, an overcoat 180, a transflective member 192, pixel electrodes 191R, 191G, 191B, and 191W, an insulating member 361, a white organic light emitting member 370, and a common electrode 270 are sequentially formed on an insulation substrate 110.

Differently from the embodiment of FIG. 3, the present embodiment does not include any transparent member, but protrusions and depressions OEg and OEw (or embossing) are formed on the surface of the overcoat 180 in the green pixel G and in the protrusion and depression region Wgc of the white pixel W. Accordingly, the transflective member 192, the pixel electrode 191G, the white organic light emitting member 370, and the common electrode 270 deposited on the overcoat 180 also include protrusions and depressions.

These protrusions and depressions OEg and OEw vary the light path length between the transflective member 192 and the common electrode 270 such that light corresponding to green wavelength may be intensified in green pixel G and the protrusion and depression region Wgc of the white pixel W. The thickness and refractive indexes of thin films disposed between the transflective member 192 and the common electrode 270 in the red and blue pixels R and B and the non-protrusion and depression region Wrbc of the white pixel W may be controlled, thereby intensifying light corresponding to wavelengths of red and blue.

Also, the protrusions and depressions OEg and OEw scatter light such that color variation according to viewing angles may be prevented.

Also, by controlling the ratio of area of the protrusion and depression region Wgc and the non-protrusion and depression region Wrbc of the white pixel W, white light having high luminance may be emitted in the white pixel W, variation of color coordinates of white color may be prevented, and color variation according to viewing angles may be reduced.

Finally, an organic light emitting device according to another embodiment of the present invention will be described with reference to FIG. 19.

The embodiment of FIG. 19 has almost the same cross-sectional structure as the organic light emitting device of FIG. 8. The same description as of the embodiment of FIG. 8 is omitted, and the same constituent elements are indicated by the same reference numerals.

A thin film transistor array, an insulating layer 112, an overcoat 180, a plurality of reflective members 192Rf, 192Gf, 192Bf, and 192Wf, pixel electrodes 191R, 191G, 191B, and 191W, an insulating member 361, a white organic light emitting member 370, a common electrode 270, a lower overcoat 220, a plurality of color filters 230R, 230G, 230B, and 230W, and an upper overcoat 240 are sequentially formed on an insulation substrate 110.

Differently from the embodiment shown in FIG. 8, the present embodiment includes reflective members 192Rf, 192Gf, 192Bf, and 192Wf disposed on the overcoat 180.

The reflective members 192Rf, 192Gf, 192Bf, and 192Wf include lower oxide conductive members 193Rf, 193Gf, 193Bf, and 193Wf that may be made of ITO or IZO and reflective metal members 194Rf, 194Gf, 194Bf, and 194Wf disposed on the lower oxide conductive members 193Rf, 193Gf, 193Bf, and 193Wf. The reflective metal members 194Rf, 194Gf, 194Bf, and 194Wf may be made of an opaque conductive material such as aluminum or an aluminum alloy, silver or a silver alloy, Au, Pt, Ni, Cu, W, or alloys thereof.

The common electrode 270 may be made of a metal including calcium (Ca), barium (Ba), magnesium (Mg), aluminum, or silver.

The color filters 230R, 230G, 230B, and 230W are disposed on the common electrode 270, and the upper and lower overcoats 220 and 240 may be made of an (organic) insulating material.

Differently from the embodiment of FIG. 8, the present embodiment does not include any transparent member. Instead, protrusions and depressions OEg and OEw are formed on the surface of the overcoat 180 in the green pixel G and the protrusion and depression region Wgc of the white pixel W. The effects and characteristics according to the protrusions and depressions are the same as those of the embodiment shown in FIG. 18.

The organic light emitting device according to the present embodiment emits light upward from the substrate 110 to display images, like the organic light emitting device of FIG. 17.

In the organic light emitting device of FIG. 3 to FIG. 19, the position and structure of the region where the transparent member or the protrusions and the depressions of the white pixel W are formed may be changed. Also, the components and disposition of the color filters and the organic light emitting member may be variously changed.

Although, in the present embodiments, constructive interference is generated to simultaneously enhance light corresponding to the wavelengths of red and the blue and to enhance light corresponding to green wavelength through a different condition in the white pixel W, the thickness of thin films disposed between the transflective member or the reflective member and the common electrode of the white pixel W may be selected to have three different thicknesses so that light corresponding to wavelengths of red, green and blue undergoes constructive interference under different conditions from each other to obtain white light.

According to an embodiment of the present invention, deviation of color purity according to viewing angles may be reduced, and color variation of white light according to viewing angles may be minimized. Also, defects of the white pixels may be reduced under a manufacturing process such that the yield of products may be increased.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting device comprising a first pixel displaying a first color, a second pixel displaying a second color, a third pixel displaying a third color, and a white pixel displaying a white color,
wherein each of the first, second, third, and white pixels comprises:
a transflective member;
a pixel electrode disposed on the transflective member;
an organic light emitting member disposed on the pixel electrode; and
a common electrode disposed on the organic light emitting member,
wherein the first pixel further comprises a first light path control member disposed under the common electrode, and
wherein a portion of the white pixel comprises a white light path control member disposed under the common electrode.

2. The organic light emitting device of claim 1, wherein
at least one of the first light path control member and the white light path control member comprises a thin film made of a transparent material.

3. The organic light emitting device of claim 2, wherein
the first light path control member and the white light path control member have the same thickness.

4. The organic light emitting device of claim 3, wherein
the first light path control member and the white light path control member are formed through the same process.

5. The organic light emitting device of claim 2, wherein
at least one of the first light path control member and the white light path control member comprises at least one of ITO, IZO, silicon oxide, and silicon nitride.

6. The organic light emitting device of claim 1, further comprising
an overcoat disposed under the transflective members of the first, second, third, and white pixels.

7. The organic light emitting device of claim 6, wherein
at least one of the first light path control member and the white light path control member comprises protrusions and depressions formed on a surface of the overcoat.

8. The organic light emitting device of claim 7, wherein
an inclination angle of the protrusions and depressions of the first pixel is the same as an inclination angle of the protrusions and depressions of the white pixel.

9. The organic light emitting device of claim 1, wherein
the transflective member comprises a transflective metal member comprising silver (Ag) or aluminum (Al).

10. The organic light emitting device of claim 9, wherein
a thickness of the transflective metal member is in a range of about 50 Å to about 200 Å.

11. The organic light emitting device of claim 9, wherein
the transflective member further comprises an oxide conductive member disposed on or under the transflective metal member.

12. The organic light emitting device of claim 11, wherein
the oxide conductive member comprises ITO or IZO.

13. The organic light emitting device of claim 9, wherein
the pixel electrode comprises ITO or IZO.

14. The organic light emitting device of claim 1, wherein
the transflective member comprises a first thin film and a second thin film.

15. The organic light emitting device of claim 14, wherein
the first thin film comprises silicon oxide, and the second thin film comprises silicon nitride.

16. The organic light emitting device of claim 14, wherein
the first thin film comprises ITO or IZO, and the second thin film comprises at least one of silicon oxide and silicon nitride.

17. The organic light emitting device of claim 1, wherein
the organic light emitting member is a white organic light emitting member, and
the first, second, and third pixels further comprise a first color filter, a second color filter, and a third color filter respectively disposed under the transflective member.

18. The organic light emitting device of claim 1, wherein
the organic light emitting member comprises first, second, third, and white organic light emitting members respectively disposed in the first, second, third, and white pixels.

19. The organic light emitting device of claim 1, further comprising
a second light path control member disposed under the common electrode in the second pixel.

20. The organic light emitting device of claim 19, wherein
the first, second, and white light path control members are simultaneously formed.

21. The organic light emitting device of claim 1, further comprising
a driving transistor electrically connected to the pixel electrode,
wherein the transflective member comprises a conductive material and is connected to the drain electrode of the driving transistor.

22. The organic light emitting device of claim 1, further comprising
a driving transistor electrically connected to the pixel electrode,
wherein the transflective member comprises an inorganic insulating material, and
the pixel electrode is connected to the drain electrode of the driving transistor.

23. The organic light emitting device of claim 1, further comprising
a driving transistor electrically connected to the pixel electrode,
wherein at least one of the first and white light path control members comprises a thin film made of a conductive material, and
the at least one of the first and white light path control members which comprises the thin film made of the conductive material is connected to a drain electrode of the driving transistor.

24. The organic light emitting device of claim 1, wherein:
the first color, the second color, and the third color are red, green, and blue, respectively.

25. An organic light emitting device comprising a first pixel displaying a first color, a second pixel displaying a second color, a third pixel displaying a third color, and a white pixel displaying a white color,
wherein each of the first, second, third, and white pixels comprises:
a reflective member;
a pixel electrode disposed on the reflective member;
an organic light emitting member disposed on the pixel electrode; and
a transflective common electrode disposed on the organic light emitting member,
wherein the first pixel further comprises a first light path control member disposed between the common electrode and the reflective member, and
wherein a portion of the white pixel further comprises a white light path control member disposed between the common electrode and the reflective member.

26. The organic light emitting device of claim 25, wherein
the reflective member comprises a reflective metal member made of at least one of aluminum, silver, Au, Pt, Ni, Cu, W, or alloys thereof.

27. The organic light emitting device of claim 26, wherein
the reflective member further comprises an oxide conductive member disposed on or under the reflective metal member.

28. The organic light emitting device of claim 27, wherein
the oxide conductive member comprises ITO or IZO.

29. A method for manufacturing an organic light emitting device comprising a first pixel displaying a first color, a second pixel displaying a second color, a third pixel displaying a third color, and a white pixel displaying a white color, the method comprising:
forming a transflective member on a substrate of each of the first, second, third, and white pixels;
forming a first light path control member on the transflective member of at least one of the first, second, and third pixels, and a white light path control member on a portion of the transflective member of the white pixel;
forming a pixel electrode in each of the first, second, third, and white pixels;
forming an organic light emitting member on the pixel electrode; and
forming a common electrode on the organic light emitting member,
wherein the first light path control member and the white light path control member are formed through a same process.

30. The method of claim 29, wherein
the forming of the transflective member comprises
depositing a transflective member layer comprising at least two materials having different refractive indexes; and
patterning the transflective member layer by photolithography.

31. The method of claim 29, wherein
the forming of the transflective member comprises:
sequentially depositing a lower transparent conductive layer, a metal layer, and an upper transparent conductive layer; and
patterning the lower transparent conductive layer, the metal layer, and the upper transparent conductive layer by photolithography.

32. The method of claim 31, wherein
the lower transparent conductive layer and the upper transparent conductive layer comprise at least one of ITO and IZO, and the metal layer comprises at least one of silver and aluminum.

33. The method of claim 29, wherein
at least one of the first light path control member and the white light path control member comprise at least one of silicon nitride, silicon oxide, ITO, and IZO.
